(19) United States
(12) Patent Application Publication
(10) Pub. No.: US 2025/0208524 A1
(43) Pub. Date: Jun. 26, 2025

(54) HOLDING DEVICE FOR AN OPTICAL COMPONENT HAVING AN OPTICAL SURFACE WITH A POLYGONAL BORDER AND HAVING A CYLINDRICAL SUBSTRATE BODY

(71) Applicant: Carl Zeiss SMT GmbH, Oberkochen (DE)

(72) Inventors: Eva Linda MATHIEU, Heidenheim (DE); Ludovico CRISTIANO, Weilminster (DE); Christian KRUG, Rabenau (DE); Simon CRISTIANO, Weilminster (DE); Maximilian KRUSCHE, Heuchelheim (DE)

(21) Appl. No.: 19/076,000

(22) Filed: Mar. 11, 2025

Related U.S. Application Data
(63) Continuation of application No. PCT/EP2023/074063, filed on Sep. 1, 2023.

(30) Foreign Application Priority Data
Sep. 20, 2022 (DE) 102022209869.2

(51) Int. Cl. G03F 7/00; B25J 15/00; G02B 7/00

(52) U.S. Cl. CPC G03F 7/70825; B25J 15/0033; G03F 7/7015; G03F 7/70591; G02B 7/00

(57) ABSTRACT

A holding device holds an optical component having an optical surface with a polygonal border and having a cylindrical substrate body with a cylinder lateral wall with a polygonal cross section corresponding to the border of the optical surface. The holding device has a holding frame. At least two bearing bodies of the holding device make bearing contact with the lateral wall of the substrate body by way of bearing portions of the lateral wall. At least one pressing body of the holding device exerts a bearing pressure that presses the substrate body against the bearing body. The holding device can securely hold optical components having an optical surface with a polygonal border and having a cylindrical substrate body and moreover enables positionally accurate mounting.

### CROSS-REFERENCE TO RELATED APPLICATIONS

The present application is a continuation of, and claims benefit under 35 USC 120 to, international application No. PCT/EP2023/074063, filed Sep. 1, 2023, which claims benefit under 35 USC 119 of German Application No. 10 2022 209 869.2, filed Sep. 20, 2022. The entire disclosure of each of these applications is incorporated by reference herein.

### FIELD

The disclosure relates to a holding device for an optical component having an optical surface with a polygonal border and having a cylindrical substrate body. The disclosure also relates to an optical assembly comprising such a holding device, to a method for determining the position of an optical component in such a holding device, to an illumination optical unit comprising such an optical assembly, to an optical system comprising such an illumination optical unit, to an illumination system comprising such an optical system, and to a projection exposure apparatus comprising such an illumination system.

### BACKGROUND

A holding device for an optical component in the form of a rod of an illumination device is known from DE 10 2007 050 456 A1.

DE 102 55 735 A1 discloses a device for mounting a reflector rod. DE 103 11 809 A1 discloses a polarization-optimized illumination system. CN 209 132 491 U discloses a holding structure for an optical integrator.

### SUMMARY

The present disclosure seeks to provide a holding device which makes it possible to securely hold optical components having an optical surface with a polygonal border and having a cylindrical substrate body and which can result in positionally accurate mounting.

In an aspect, the disclosure provides a holding device for an optical component having an optical surface with a polygonal border and having a cylindrical substrate body with a cylinder lateral wall with a polygonal cross section corresponding to the border of the optical surface. The holding device comprises: a holding frame; at least two bearing bodies for making bearing contact with the lateral wall of the substrate body by way of bearing portions of the lateral wall; and at least one pressing body for exerting a bearing pressure, which presses the substrate body against the bearing bodies. At least one pressing body is disposed such that it presses directly on the lateral wall of the substrate body.

According to the disclosure, it was recognized that the mount can be subdivided into functional groups, specifically for the one part a bearing body for defining a bearing point for the lateral wall of the substrate body, and at least one pressing body which presses a substrate body of the optical component against the bearing body. This can help provide defined and for example positionally accurate mounting of the optical component. The at least two bearing bodies and/or the at least one pressing body may be in contact with the cylinder lateral wall of the substrate body by way of a respective contact point. The optical component may be an optical rod, which can be used for example for light mixing in a projection exposure apparatus for microlithography. The polygon for defining the optical surface with a polygonal border of the optical component is an n-gon with n corners, with n being greater than 4, for example a pentagon, a hexagon or an octagon. n is usually less than 100. A position of the holding frame of the holding device may be defined by a position of a holding mount of the holding device.

The holding device makes it possible to enable open-loop or closed-loop control of the definition of the position of the optical component. To that end, the holding device may have at least one displacement actuator for at least one of the bearing bodies and optionally also a position sensor.

The holding device can comprise at least two holding bodies. Such embodiments of the holding device have proven successful in practice. The at least two pressing bodies can press on the lateral wall of the substrate body by way of assigned bearing portions of the lateral wall of the substrate body in one and the same cross-sectional plane. The substrate body is held in defined fashion at an axial position between its two optical surfaces as a result. The holding device may have exactly three pressing bodies, which define a holding plane via their assigned bearing portions, by way of which they press on the lateral wall of the substrate body. This holding plane may be perpendicular to a cylindrical axis of the substrate body, that is to say parallel to the cross-sectional plane of the cylinder lateral wall. This can apply, for example, in embodiments in which two of the pressing bodies can be designed such that the bearing pressures act on the substrate body of the optical component from different directions, optionally with the bearing pressures of the two pressing bodies can act in opposite directions.

At least one of the bearing bodies can be in the form of a manipulator. In such embodiments, the holding device can allow for open-loop or optionally closed-loop control of the definition of the position for the optical component. In the event of manipulation, the bearing body can then be adjusted towards and/or away from the bearing portion. Such an adjustment may be performed by a motor. The bearing body may in that case have an adjustment actuator.

The holding device can comprise three bearing bodies, optionally with the three bearing bodies specifying a concave contact geometry, into which a convex cross-sectional region of the optical component can be pressed by the at least one pressing body. Such embodiments can allow for a defined positional geometry.

An optical assembly can comprise a holding device according to the disclosure and also an optical component held thereby. Features of such optical assemblies correspond to those that have already been explained above with reference to the holding device.

In some embodiments of an optical assembly, the holding device comprises two pressing bodies with the bearing pressures acting in opposite directions such that they press against mutually parallel surfaces of the lateral wall. In such embodiments, the bearing bodies can be used to positionally define the optical component relative to the holding device.

The disclosure also seek to provide a method for determining the position of the optical component when the holding device is in use.

In an aspect, the disclosure provides a method for determining the position of an optical component having an optical surface with a polygonal border and having a cylindrical substrate body with a cylinder lateral wall with a polygonal cross section corresponding to the border of the optical surface. The optical component is held in a holding device according to the disclosure. The method comprises: determining an angle between two polygon faces of the cylinder lateral wall; determining a relative position of at least two mutually spaced-apart contact points, by way of which the bearing bodies are in contact with the cylinder lateral wall, wherein one of the bearing bodies makes contact with one of the two polygon faces and another one of the bearing bodies makes contact with the other one of the two polygon faces, with respect to at least two frame points of the holding device; and determining a relative position of the cross section of the cylinder lateral wall with respect to the holding device from the determined angle and the determined relative position.

Determination of an angle and at least two relative positions of bearing body contact points makes it possible to determine a relative position of the cross section of the cylinder lateral wall of the optical component in the holding device.

Related illumination optical units, optical systems, illumination systems, and projection exposure apparatus correspond to those that have already been explained above with reference to the holding device, the optical assembly and the position determining method.

The illumination system can have a DUV (deep ultraviolet) light source.

For example, a microstructured or nanostructured component, especially a semiconductor chip, for example a memory chip, can be produced using the projection exposure apparatus.

### BRIEF DESCRIPTION OF THE DRAWINGS

Exemplary embodiments of the disclosure are explained in greater detail below with reference to the drawing, in which:

FIG. 1 shows a schematic overview of a projection exposure apparatus for microlithography in a meridional section, having an optical rod for mixing illumination light;

FIG. 2 shows a cross section through an embodiment of the optical rod in a holding device, which is not illustrated in FIG. 1;

FIG. 3 shows a further embodiment of the optical rod in a further embodiment of the holding device in an illustration similar to FIG. 2;

FIG. 4 schematically shows parameters which play a role in determining the position of the rod in the holding device and in FIG. 3.

### DETAILED DESCRIPTION

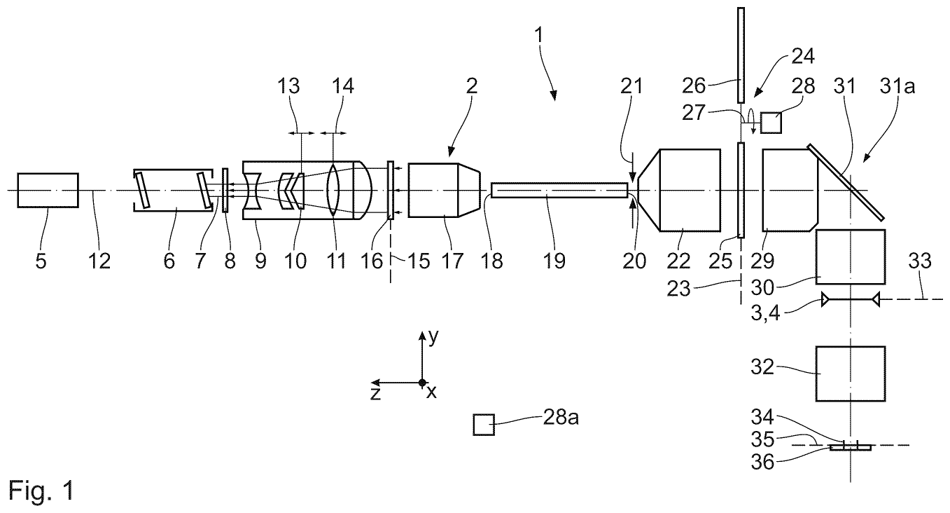

In order to elucidate positional relationships, a Cartesian xyz-coordinate system is specified in the drawing. In FIG. 1, the x axis extends perpendicularly to and beyond the plane of the drawing. The y axis extends upwards in FIG. 1. The z axis extends to the left in FIG. 1.

A projection exposure apparatus 1 for microlithography has an illumination system comprising an illumination optical unit 2 for illuminating a defined illumination and object field 3 at the location of an object and a reticle 4, which represents a template to be projected for the production of microstructured or microelectronic semiconductor components. The reticle 4 is held by a reticle holder, which is not illustrated here.

A laser in the deep ultraviolet (DUV) is used as a light source 5 for the illumination light of the illumination system. This could be an ArF excimer laser. Other DUV sources are also possible.

A beam expander 6, for example a mirror arrangement known from DE-A 41 24 311, is used to reduce coherence and generate an expanded, collimated, rectangular cross section of a beam of the illumination light 7.

A first diffractive optical raster element (DOE) 8 is disposed in an object plane of a condenser 9. This DOE 8 is also referred to hereinafter as intensity specification element. The condenser 9 comprises an axicon pair 10 and a lens element 11 with a positive focal length. The spacing between the axicon elements of the axicon pair 10 and the position of the lens element 11 are adjustable along an optical axis 12 of the illumination optical unit 2, as indicated by double-headed arrows 13, 14 in FIG. 1. Therefore, the condenser 9 represents a zoom optical unit.

A further diffractive and/or refractive optical raster element (ROE) 16 is disposed in an exit pupil plane 15 of the condenser 9. Where the raster element 16 is diffractive, it may be in the form of a computer-generated hologram (CGH), for example. As an alternative or in addition to the embodiment as a diffractive optical element, the ROE 16 may be refractive, for example in the form of a refractive optical raster element, such as a microlens array. Although a diffractive embodiment is possible, the raster element 16 is denoted ROE below.

Using the first DOE 8, a defined intensity distribution in the pupil plane 15 is set at the location of the ROE 16. This generates a specified so-called illumination setting, i.e., a defined distribution of illumination angles over the object field 3. Therefore, the first DOE 8 represents an illumination angle specification element for specifying an illumination angle distribution over the object field 3.

An input coupling optical unit 17 downstream of the ROE 16 transmits the illumination light to an end-side entry surface 18 of a transparent optical rod in the form of a glass rod 19. Variants for the optical rod 19 and variants of holding devices for the optical rod 19 are also described below.

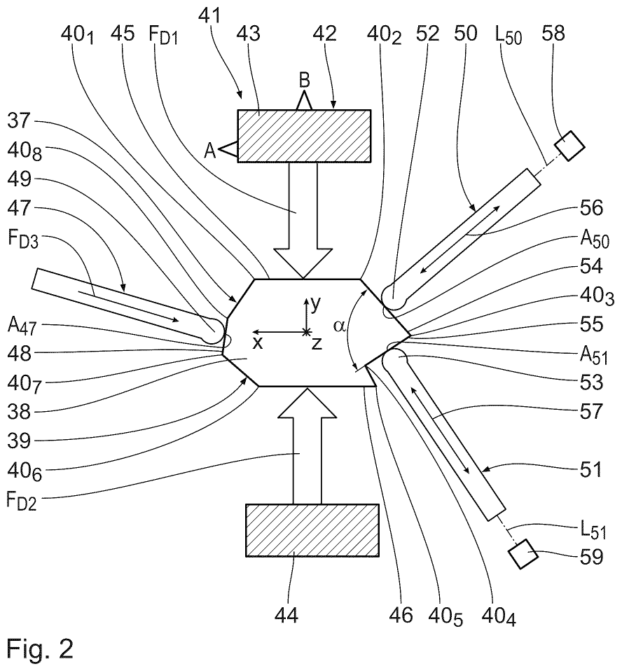

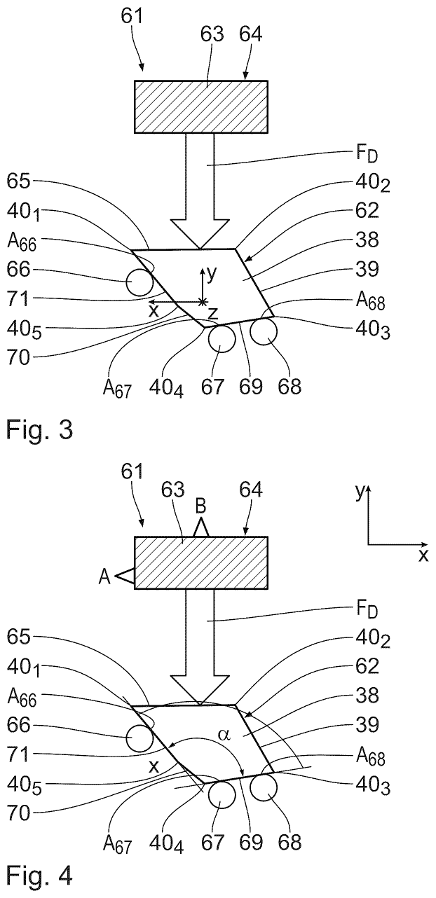

The optical rod 19 has a cross section which differs from a square or rectangular cross section. This rod cross section is generally polygonal and may for example be hexagonal. Other cross section examples are also described below on the basis of FIGS. 2 and 3.

The rod 19 mixes and homogenizes the illumination light by multiple internal reflection at the lateral walls of the rod 19. An intermediate field plane in which a reticle masking system (REMA) 21, an adjustable field stop, is disposed is located directly on an end-side exit surface 20 of the rod 19 which is situated opposite the entry surface 18.

The ROE 16 is used, inter alia, to adapt the cross-sectional shape of the illumination beam 7 to the rectangular shape of the entry surface 18 of the rod 19.

The ROE 16 is also referred to hereinafter as optical rod illumination specification element. The ROE 16 serves to specify an illumination of the entry surface 18 of the rod 19 by way of the illumination light 7. The illumination of the entry surface 18 is specified in such a way that it specifies the distribution of the illumination intensity and, at the same time, the illumination angle distribution over the entry surface 18. The specified illumination intensity distribution over the entry surface 18 deviates from a homogeneous distribution, as is yet to be explained in more detail below.

The DOE 8, i.e., the intensity specification element, is used to specify an illumination intensity distribution on the ROE 16, i.e., on the optical rod illumination specification element.

A condenser 22 is downstream of the REMA 21. A stop interchange holder 24 with a plurality of stops or filters can be disposed in an exit pupil plane 23 of the condenser 22, of which two stops 25, 26 are illustrated in FIG. 1. The stop interchange holder 24 carries the various stops in the manner of a stop carousel. For the purpose of changing the stop, the carousel is driven around a drive shaft 27 of a drive motor 28, which is signal-connected to a central open-loop control device 28a of the projection exposure apparatus 1. The stops of the stop interchange holder 24 are subdivided into an even number of separate stop portions. The stop portions may be stops that completely block the illumination light, neutral density filters that attenuate the illumination light by a defined percentage, or polarization filters that linearly polarize the illumination light.

A further condenser with lens-element groups 29, 30 is downstream of the pupil plane 23 that is downstream of the rod 19. A 90° deflection mirror 31 for the illumination light is disposed between the two lens-element groups 29, 30. The condenser 22 and the further condenser with the two lens-element groups 29, 30 form a lens 31a, which images the intermediate field plane of the REMA 21 onto the reticle 4. The pupil plane 23 represents an internal pupil plane of this lens 31a.

A projection lens 32 images the object field 3, which lies in an object plane 33, into an image field 34 in an image plane 35. The image field 34 is part of the surface of a wafer 36 that is to be exposed, the wafer being provided with a coating which is sensitive to the illumination light. The wafer 36 is held by a wafer holder, which is not shown here. During the projection exposure, the reticle 4 and the wafer 36 are scanned synchronously with one another. An intermittent displacement of the holder of the reticle 4 and of the wafer 36, a so-called stepper operation, is also possible.

With the exception of the deflection mirror 31, the various beam-guiding or beam-shaping components of the projection exposure apparatus 1 are indicated as refractive components. However, they could equally be catadioptric or reflective components.

FIG. 2 shows a cross section through a variant of an optical rod 37 which can be used in the projection exposure apparatus 1 instead of the optical rod 19. The optical rod 37 is an optical component having an optical surface with a polygonal border, that is to say an entry surface 18 with a polygonal border and an exit surface 20 (cf. also FIG. 1). The optical rod 37 has a cylindrical substrate body or main body 38 comprising a cylinder lateral wall 39 with a polygonal cross section which corresponds to the border of the optical surfaces 18, 20.

Overall, the optical surfaces 18, 20 of the rod 37 have an octagonal polygonal border, with corresponding corners 40 of this cross-sectional polygon being numbered consecutively, starting from the upper left corner in FIG. 2 and going clockwise, and being indexed with 40₁ to 40₈ Seven of the eight corners 40ᵢ are convex corners of the substrate body 38. Only one of the eight corners, the corner 40₄, is a concave corner of the substrate body 38. A polygon internal angle of the substrate body 38 is thus greater than 180° in the region of the corner 40₄. All other polygon internal angles are smaller than 180°.

There are planar portions of the lateral wall 39 between the corners 40ᵢ that extend perpendicularly to the plane of the drawing in FIG. 2 and parallel to one another between the entry surface 18 and the exit surface 20 of the rod 37.

The optical rod 37 is held by a holding device 41 and positioned in defined fashion in its spatial position. The holding device 41 has a holding frame 42 with two mount bodies 43, 44. The mount bodies 43, 44 are pressing bodies for pressing the holding frame 41 into contact with the lateral wall 39 of the substrate body 38 by way of portions 45, 46 to be pressed of the lateral wall 39. The portion 45 to be pressed is between the corners 40₁ and 40₂. The portion 46 to be pressed is between the corners 40₅ and 40₆. The portions 45, 46 to be pressed are wall portions of the lateral wall 39 that extend parallel to one another.

The pressing bodies 43, 44 exert bearing pressures F_{D1}, F_{D2} on the portions 45, 46 to be pressed. These bearing pressures F_{D1}, F_{D2} are illustrated by arrows in FIG. 2.

The bearing pressures F_{D1}, F_{D2} act in opposite directions. The bearing pressures F_{D1}, F_{D2} act perpendicularly to the portions 45 and 46 to be pressed.

The holding device 41 has a further pressing body 47, which is in the form of a pressure piece. The pressing body 47 bears against a portion 48 to be pressed of the lateral wall 39 between the corners 40₇ and 40₈ (contact point A₄₇). This bearing contact is effected via a crowned pressing body end portion 49. The bearing of the pressing body end portion 49 against the portion 48 to be pressed of the lateral wall 39 may approximate punctiform contact or else, depending on the embodiment of the pressing body end portion 49, linear contact, with a line of this linear contact extending perpendicularly to the plane of the drawing of FIG. 2, that is to say parallel to the corner lines of the corners 40ᵢ. The pressing body end portion 49 may be designed in the manner of a convex, crowned cylinder portion.

A bearing pressure exerted by the pressing body 47 along its longitudinal axis on the portion 48 to be pressed is depicted in FIG. 2 by an arrow F_{D3}.

The bearing pressures F_{D1}, F_{D2} and F_{D3} all act in the plane of the drawing of FIG. 2, that is to say parallel to the xy plane. The bearing pressure F_{D3} extends at an acute angle in relation to the xz plane. The pressure F_{D1} acts in the negative x direction. The pressure F_{D2} acts in the positive y direction.

The three pressing bodies 43, 44, 47 of the holding device 41 serve to exert a bearing pressure, which presses the substrate body 38 of the rod 37 against a bearing of the holding device 41, the bearing being formed by two bearing bodies 50, 51 of the holding device 41.

The bearing bodies 50, 51 are in the form of manipulators or positioning elements. Bearing body end portions 52, 53 of the bearing bodies 50, 51 exert a bearing contact pressure on the lateral wall 39 of the substrate body 38 by way of bearing portions 54, 55 of the lateral wall 39. The bearing body end portions 52, 53 may be designed like the pressing body end portion 49 of the pressing body 47.

The bearing portion 54 is between the corners 40₂ and 40₃ of the lateral wall 39. The bearing portion 55 is between the corners 40₃ and 40₄ of the lateral wall 39.

The bearing bodies 50, 51 are in the form of manipulators. The bearing bodies 50, 51 may be in the form of adjusting screws. The bearing bodies 50, 51 may, as indicated by double-headed arrows 56, 57 in FIG. 2, be adjusted with a defined position towards and away from the bearing portions 54, 55. The adjustment direction extends along respective longitudinal axes L₅₀, L₅₁ of the bearing bodies 50, 51. This adjustment is effected by adjustment actuators 58, 59, which are indicated schematically in FIG. 2.

The adjustment direction 56 of the bearing body 50 extends at approximately 45° in relation to the xz and the yz plane. The adjustment direction 57 extends at approximately 60° in relation to the xz plane and 30° in relation to the yz plane. Other angles of the adjustment directions 56, 57 in relation to these planes, xz and yz, in the range between 10° and 80° are also possible.

Together with the optical rod 37, the holding device 41 forms an optical assembly of the projection exposure apparatus 1.

To determine the position of the optical component 37, that is to say of the rod, in the coordinates of the holding frame 42 the following procedure is carried out:

An angle α between two polygon faces of the cylinder lateral wall 39 is determined, for example the angle between the bearing portions 54 and 55.

Relative positions between contact points A₅₀, A₅₁, via which the bearing bodies 50, 51 are in contact with the lateral wall 39, with respect to one another and to two frame points A, B of the holding frame 42 are determined.

It is then possible to determine the relative position of the polygonal cross section of the cylinder lateral wall 39 with respect to the holding device 41 from these data α, A₅₀, A₅₁, A and B. In addition, it is also possible to use knowledge of the position of a further point of the cylinder lateral wall 39, for example the position of a contact point A₄₇ of the pressing body 47 with the portion 48 to be pressed of the lateral wall 39 or the position of a further point, for example in the region of the bearing portions 54 or 55 of the cylinder lateral wall 39, to determine the relative position of the polygonal cross section of the cylinder lateral wall 39 with respect to the holding device 41. Contact points by way of which the pressing bodies 43, 44 of the holding device 47 bear against the portions 45, 46 to be pressed of the cylinder lateral wall may also be such an additional relative position which, when known, makes it possible to determine the relative position of the polygonal cross section of the cylinder lateral wall 39 with respect to the holding device 41.

On the basis of FIG. 3, another embodiment of a holding device 61 for mounting, with a defined position, another embodiment of an optical component that has an optical surface with a polygonal border and is in the form of an optical rod 62 will be described below. Components and functions corresponding to those which have already been explained above with reference to FIGS. 1 and 2 have the same reference numerals and will not be discussed in detail again.

The holding device 61 has a pressing body 63, which is a mount body of a mount of a holding frame 64 of the holding device 61.

The optical rod 62 is in turn designed with a substrate body 38 having a polygonal cross section, which in the case of the optical rod 62 has a convex pentagonal (corners 40₁ to 40₅) configuration.

The pressing body 63 exerts a pressure FD on a portion 65 to be pressed of the lateral wall 39 of the rod 62. This causes the rod 62 to be pressed into a bearing formed by three bearing bodies 66, 67, 68, which specify a concave contact geometry. A convex cross-sectional region of the optical rod 62, formed by bearing portions 69, 70, 71, between the corners 40₃, 40₄, the corners 40₄ and 40₅ and the corners 40₅ and 40₁ is pressed into this concave contact geometry of the bearing bodies 66 to 68. The bearing bodies 66 to 68 are in turn formed by bearing body end portions in the manner of the bearing body end portions 52, 53 of the embodiment according to FIG. 2 and can ensure punctiform contact or linear contact with the bearing portions 69 to 71 of the lateral wall 39.

On the basis of FIG. 4, the way in which the position of the optical rod 62 is determined when the holding device 61 is in use will be described below.

First of all, in turn an angle α between two polygon faces of the cylinder lateral wall 39 is determined, in this case between the bearing portions 69 and 71. Then, a relative position of contact points A₆₆, A₆₇, A₆₈, by way of which the bearing bodies 66 to 68 bear against the bearing portions 69 to 71 of the lateral wall 39, with respect to two frame points A and B of the pressing body 63 of the holding frame 61 is determined. The relative position of the cross section of the cylinder lateral wall 39 and thus the relative position of the rod 62 with respect to the holding device 61 is then determined from these parameters α, A₆₆ to A₆₈, A and B.

To determine the position of the optical component 37, 62 in the respective holding device 41, 61, it is alternatively or additionally possible also to use at least one position sensor, such as a distance sensor. Such a position sensor can determine the respective position, for example of one of the bearing bodies 50, 51 (FIG. 2) or 66 to 68 (FIG. 3). The pressing body 47 of the embodiment according to FIG. 2 can also have such a position sensor.

A corresponding position sensor can be used for closed-loop control of the positioning of the bearing bodies 50, 51. To that end, the actuators 58, 59 and the at least one position sensor are signal-connected to the open-loop control device 28a, which is then also in the form of a closed-loop control device, of the projection exposure apparatus 1.

The mount of the holding device 41 or 61 may have a cylindrical overall form, this not being illustrated in the drawing.

In the case of the microlithographic production of a microstructured or nanostructured component, the wafer 36 is initially coated, at least in certain portions, with a light-sensitive layer. Then, a structure on the reticle 4 is projected onto the wafer 36 using the projection exposure apparatus 1. After that, the exposed wafer 36 is processed to form a microstructured component.

What is claimed is:

1. A holding device configured to hold an optical component comprising an optical surface with a polygonal border, the optical component comprising a cylindrical substrate body with a cylinder lateral wall with a polygonal cross section corresponding to the polygonal border of the optical surface, the holding device comprising:
a holding frame;
at least two bearing bodies configured to make bearing contact with the lateral wall of the substrate body via bearing portions of the lateral wall; and
at least two pressing bodies configured to exert bearing pressures acting on the substrate body from opposite directions.

2. The holding device of claim 1, wherein the at least two pressing bodies are configured to press directly on the lateral wall of the substrate body.

3. The holding device of claim 1, wherein the at least two pressing bodies press on the lateral wall of the substrate body via assigned bearing portions of the lateral wall of the substrate body in one and the same cross-sectional plane.

4. The holding device of claim 3, comprising exactly three pressing bodies, wherein the exactly three pressing bodies define a holding plane via their assigned bearing portions.

5. The holding device of claim 4, wherein the holding plane is perpendicular to a cross-sectional plane of the cylinder lateral wall.

6. The holding device of claim 1, comprising exactly three pressing bodies, wherein the exactly three pressing bodies define a holding plane via their assigned bearing portions.

7. The holding device of claim 6, wherein the holding plane is perpendicular to a cross-sectional plane of the cylinder lateral wall.

8. The holding device of claim 1, wherein at least one of the at least two bearing bodies comprises a manipulator.

9. The holding device of claim 1, wherein each of the at least two bearing bodies comprises a manipulator.

10. The holding device of claim 1, wherein:
the at least two pressing bodies press on the lateral wall of the substrate body via assigned bearing portions of the lateral wall of the substrate body in one and the same cross-sectional plane; and
at least one of the at least two bearing bodies comprises a manipulator.

11. The holding device of claim 1, wherein the at least two bearing bodies comprise three bearing bodies.

12. The holding body of claim 11, wherein the three pressing bodies define a holding plane via their assigned bearing portions.

13. The holding device of claim 11, wherein the three bearing bodies define a concave contact geometry, and a convex cross-sectional region of the optical component is pressable into the concave contact geometry via the at least one of the at least two pressing bodies.

14. An optical assembly comprising:
an optical component, comprising:
an optical surface with a polygonal border; and a
a cylindrical substrate body with a cylinder lateral wall with a polygonal cross section corresponding to the polygonal border of the optical surface; and
a holding device, comprising:
a holding frame;
at least two bearing bodies making bearing contact with the lateral wall of the substrate body via bearing portions of the lateral wall; and
at least two pressing bodies exerting bearing pressures acting on the substrate body from opposite directions.

15. The optical assembly of claim 14, wherein the at least two pressing bodies press against mutually parallel surfaces of the lateral wall.

16. An optical unit, comprising:
an optical assembly according to claim 14,
wherein the optical unit is an illumination optical unit configured to illuminate an object field.

17. Optical system, comprising:
an illumination optical unit comprising an optical assembly according to claim 14; and
a projection optical unit,
wherein the illumination optical unit configured to illuminate an object field of the projection optical unit, and the projection optical unit is configured to image the object field into an image field of the projection optical unit.

18. An illumination system, comprising:
a light source; and
an optical system, comprising:
an illumination optical unit comprising an optical assembly according to claim 14; and
a projection optical unit,
wherein the illumination optical unit configured to illuminate an object field of the projection optical unit, and the projection optical unit is configured to image the object field into an image field of the projection.

19. A projection exposure apparatus, comprising:
an illumination system, comprising:
a light source; and
an optical system, comprising:
an illumination optical unit comprising an optical assembly according to claim 14; and
a projection optical unit;
a first holder configured to hold a first object in an object plane of the projection optical unit; and
a second holder configured to hold a second object in an image plane of the projection optical unit,
wherein the illumination optical unit is configured to illuminate the first object when the first object is in the object field, and the projection optical unit is configured to image the illuminated object in the object field into the second object when the second object is in the image field.

20. A method, comprising:
providing the holding device of claim 1 and the optical element;
determining an angle between two polygon faces of the cylinder lateral wall;
determining a relative position of at least two mutually spaced-apart contact points by which the bearing bodies contact the cylinder lateral wall, one of the bearing bodies making contact with one of the two polygon faces and another one of the bearing bodies making contact with the other one of the two polygon faces, with respect to at least two frame points of the holding device; and
determining a relative position of the cross section of the cylinder lateral wall with respect to the holding device from the determined angle and the determined relative position.
